(19) United States
(12) Patent Application Publication
(10) Pub. No.: US 2025/0093967 A1
(43) Pub. Date: Mar. 20, 2025

(54) Controlling Dynamic Range

(71) Applicant: Peratech IP Ltd., Catterick Garrison (GB)

(72) Inventor: Carl Olof Fredrik Jonsson, Gavle (SE)

(21) Appl. No.: 18/969,360

(22) Filed: Dec. 5, 2024

Related U.S. Application Data
(63) Continuation of application No. PCT/GB2023/000036, filed on Jun. 29, 2023.

(30) Foreign Application Priority Data
Jul. 1, 2022 (GB) 2209719.0

(51) Int. Cl. G06F 3/023

(52) U.S. Cl. CPC G06F 3/023

(57) ABSTRACT

An apparatus for controlling the dynamic range of a force sensing device comprises a plurality of drive lines and a plurality of sensing lines arranged to provide a plurality of intersections defining a plurality of keys. Each key comprises a sensing element which exhibits a variable resistance. A controller is configured to convert an analogue output from each sensing element to a digital output and an input amplifier is configured to provide signal gain, such that, the range of the controller is adapted by means of the signal gain. The input amplifier comprises a transimpedance amplifier connected to a gain resistor.

### CROSS REFERENCE TO RELATED APPLICATIONS

This application is a continuation of and claims priority to International Patent Application number PCT/GB2023/000036, filed on 29 Jun. 2023, which claims priority from United Kingdom Patent Application number 22 09 719.0, filed on 1 Jul. 2022. The whole contents of International Patent Application number PCT/GB2023/000036 and United Kingdom Patent Application number 22 09 719.0 are incorporated herein by reference.

### TECHNICAL FIELD

The present invention relates to an apparatus for controlling the dynamic range of a force sensing device and a method of controlling the dynamic range of a force sensing device.

### BACKGROUND OF THE INVENTION

Many modern electronic devices utilize keyboards to provide an input device to the electronic device. Conventional keyboards may utilize switch-type mechanisms in which the keys of the keyboard operate in a traditional on/off pattern. Alternative keyboards comprise a membrane in which a matrix structure includes a plurality of keys which are positioned at each intersection in the matrix.

In use, when several keys of the matrix keyboard are pressed at the same time, the flow of current through the matrix can result in activation of keys which were not pressed. This result is known as ghosting with the unpressed keys which are activated providing ‘ghost keys’. Additionally, a further problem in matrix keyboards is crosstalk, where several keys on the same row or same column of the matrix can be activated when a single key is pressed.

A further problem with keyboards of this type is that they typically comprise a large number of sensing elements configured to measure force. Often, as many sensing elements can be provided as the number of keys in the keyboard. In production and manufacture, the sensing elements may exhibit manufacturing variances, such that, in use, when a sensing element corresponding to a particular key is activated, an output response varies from each key. Thus, it can be difficult to have consistent properties and signal ranges for each sensing element. In addition, force sensors with low sensitivity or resistance change utilize a small portion of the dynamic range and consequently suffer from low sensitivity.

Conventional systems utilize voltage divider inputs with the force sensing resistors. However, these do not provide a suitable means or architecture in which to optimize both low and high force inputs.

US 2015/0349774 (Yann-Cherng Chern et al), published 3 Dec. 2015, discloses a resistive input system with resistor matrix. The apparatus includes a selective circuit and plurality of reference resistors.

U.S. Pat. No. 8,872,789 (Change-ju Lee), published 28 Oct. 2014, describes a method of calibrating a touch sensing system including a calibration circuit as part of the touch sensing system.

### BRIEF SUMMARY OF THE INVENTION

According to an aspect of the present invention, there is provided an apparatus for controlling the dynamic range of a force sensing device, as claimed in claim 1.

The apparatus may be arranged to form an electronic keyboard or be incorporated in an electronic device.

According to a second aspect of the present invention, there is provided a method of controlling the dynamic range of a force sensing device, as claimed in claim 13.

Embodiments of the invention will be described, by way of example only, with reference to the accompanying drawings. The detailed embodiments show the best mode known to the inventor and provide support for the invention as claimed. However, they are only exemplary and should not be used to interpret or limit the scope of the claims. Their purpose is to provide a teaching to those skilled in the art. Components and processes distinguished by ordinal phrases such as “first” and “second” do not necessarily define an order or ranking of any sort.

### BRIEF DESCRIPTION OF THE SEVERAL VIEWS OF THE DRAWINGS

FIG. 1 shows an electronic device comprising a keyboard having a plurality of keys;

FIG. 2 shows a schematic diagram of an example sensing array suitable for use in membrane keyboards;

FIG. 3 shows a simplified circuit diagram representing an apparatus for detecting a mechanical interaction comprising a keyboard membrane having a force sensing capacity;

FIG. 4 shows the simplified circuit diagram of FIG. 5, in which a plurality of keys has been pressed;

FIG. 5 shows a graph showing typical characteristics for a plurality of sensing elements;

FIG. 6 shows a schematic diagram of an inverted transimpedance amplifier integrated with a force sensing resistive element;

FIG. 7 shows an example embodiment having an application range and an optimized dynamic range of the analogue to digital converter;

FIG. 8 shows a schematic diagram of a circuit for optimizing the dynamic range using an offset resistor;

FIG. 9 shows an example embodiment having an optimized dynamic range for calibrated sensing elements;

FIG. 10 shows a schematic diagram of a further circuit utilizing an offset resistor;

FIG. 11 shows a schematic diagram of a circuit in a further example embodiment utilizing a gain resistor; and

FIG. 12 shows a schematic diagram of a further embodiment of a circuit comprising dynamic switching.

### DETAILED DESCRIPTION OF EMBODIMENTS OF THE INVENTION

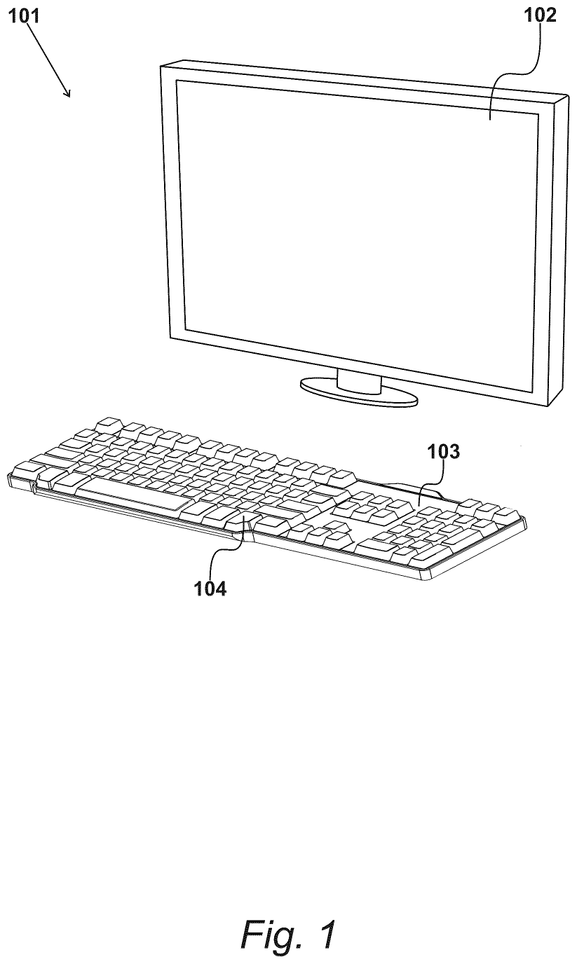

### FIG. 1

A typical scenario illustrating an electronic device comprising a keyboard. Electronic device 101 comprises a personal computer including a display 102 and keyboard 103. In the embodiment, keyboard 103 comprises a plurality of keys 104 which are arranged in the form of a keyboard membrane. When a pressure is applied to each key, each provides an input to electronic device 101 to enable control of an application running on electronic device 101.

In an embodiment, any one of the plurality of keys 104 can be utilized to control a gaming application, and, in an embodiment, for example, this may include control of a character or similar, requiring use of a multiple number of simultaneous presses on keys 104, thereby activating several keys at the same time. In this way, electronic device 101 is configured such that several keys may be pressed simultaneously, and this may occur across the keyboard membrane onto which keys 104 are positioned.

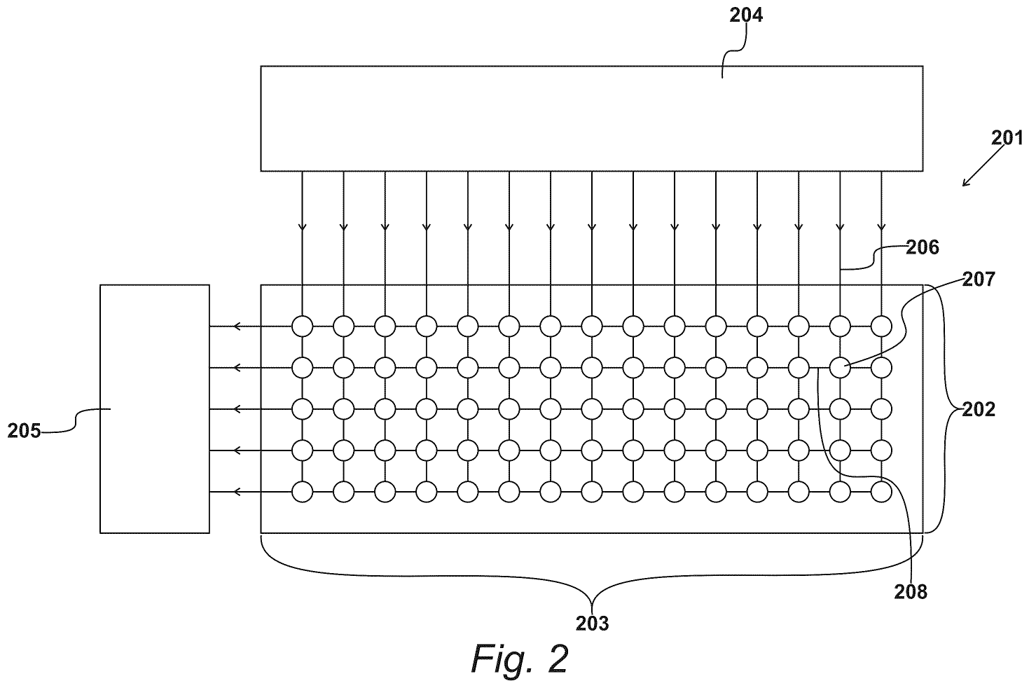

### FIG. 2

A schematic diagram of an example sensing array which forms a keyboard membrane such as that described previously with respect to FIG. 1, is shown in FIG. 2.

Sensing array 201 comprises a plurality of conductive rows 202 and a plurality of conductive columns 203. In the embodiment, a driving control unit 204 is configured to provide the plurality of conductive columns 203, or drive lines, with a voltage sequentially to allow a current to flow through the drive lines.

Sensing array 201 further comprises a sensing control unit 205 which is configured to receive an output from the plurality of conductive rows 202 or sensing lines. In the embodiment, the output is received in analogue form and converted into a digital output by means of an analogue-to-digital converter or similar as necessary.

In the embodiment, sensing array 201 comprises a plurality of sensing elements which are arranged at each intersection between the drive lines 202 and sensing lines 203. Each sensing element comprises a material which exhibits a variable resistance in response to an applied force. As each sensing element is arranged to correspond with one the plurality of keys of keyboard 103, when a force applied to a key (or sensing element), the electrical resistance of the sensing element is reduced, and a current flows through the sensing element and intersection.

In an embodiment, the sensing element comprises a quantum tunnelling material such as that sold by the present applicant Peratech Holdco Limited under the trade mark QTC®.

In an embodiment, the rows and columns are arranged on an upper conductive layer and a lower conductive layer with a sensing layer defining the sensing element applied to either the row or column. When a pressure is applied, the sensing layer is brought into contact with the opposite conductive layer and compressed to reduce the resistance of the sensing layer. In this way, the resistance of each sensing element is dependent on the applied force or area, such as the level of force applied to a key on keyboard 103.

In an alternative embodiment, the sensing elements comprise conductive finger electrodes comprising a first plurality of interdigitated fingers and a second plurality of interdigitated fingers on a single conductive layer and a second layer comprising the variably resistive material. In this way, the sensing array may provide a pressure output across two layers. It is appreciated that in further embodiments, alternative arrangements may be utilized.

Thus, in use, in the embodiment, for example, drive line 206 is driven by driving control unit 204, and when sensing element 207 is activated due to an applied force, a current flows through sensing line 208 to sensing control unit 205.

While the example described utilizes a keyboard having a keyboard membrane, it is further appreciated that the invention described herein is further applicable to alternative keyboard arrangements which utilize a plurality of sensing elements in the manner described in FIG. 2.

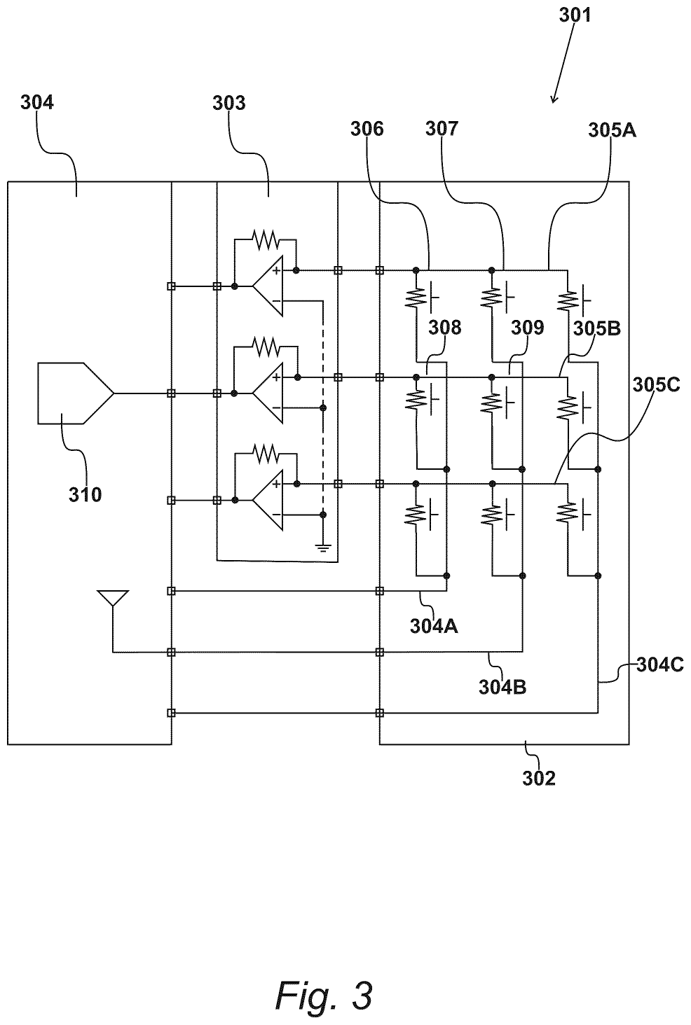

### FIG. 3

A schematic simplified circuit diagram of a keyboard membrane of a force sensing resistor enabled keyboard is shown in FIG. 3 in the form of a schematic circuit diagram.

In the embodiment, apparatus 301 comprises keyboard membrane 302, input amplifier unit 303 and controller 304.

Keyboard membrane 302 comprises a plurality of drive lines arranged as a plurality of columns 304 and a plurality of sensing lines arranged as a plurality of rows 305. At each intersection between columns 304 and rows 305 is a key, such as keys 306, 307, 308 and 309. In the embodiment, each key comprises a sensing element which exhibits a variable resistance and is represented by a variable resistor. Thus, when each key is subjected to an applied force or pressure, the resistance through the key is reduced. Measurement of this force can be made in an analogue manner by the architecture described herein which allows for a representation of the applied pressure level for a given key.

In the embodiment, the input amplifier unit 303 is illustrated as a plurality of input amplifiers which correspond to each sensing line or row. Each input amplifier is configured to provide a voltage potential to any non-activated drive lines or non-activated sensing lines. Input amplifier unit 307 provides an output voltage to controller 304, which is determined by the state of each key pressed. In the embodiment, each input amplifier comprises a transimpedance amplifier which provides a low impedance.

Controller 304 comprises a means for converting an analogue output to a digital signal for further processing. In the embodiment, this comprises an analogue to digital converter 310, which is configured to convert an analogue output from each key or sensing element when a force has been applied to the key in question to a digital output for further processing. In an alternative embodiment, the analogue to digital converter may be replaced by an alternative device such as a Schmitt Trigger to convert the output from input amplifier unit 303 from analogue to digital.

In the embodiment shown, the keyboard membrane 302 comprises three rows and three columns. It is appreciated that, in practice, many keyboard membranes are much larger but operate under substantially similar principles.

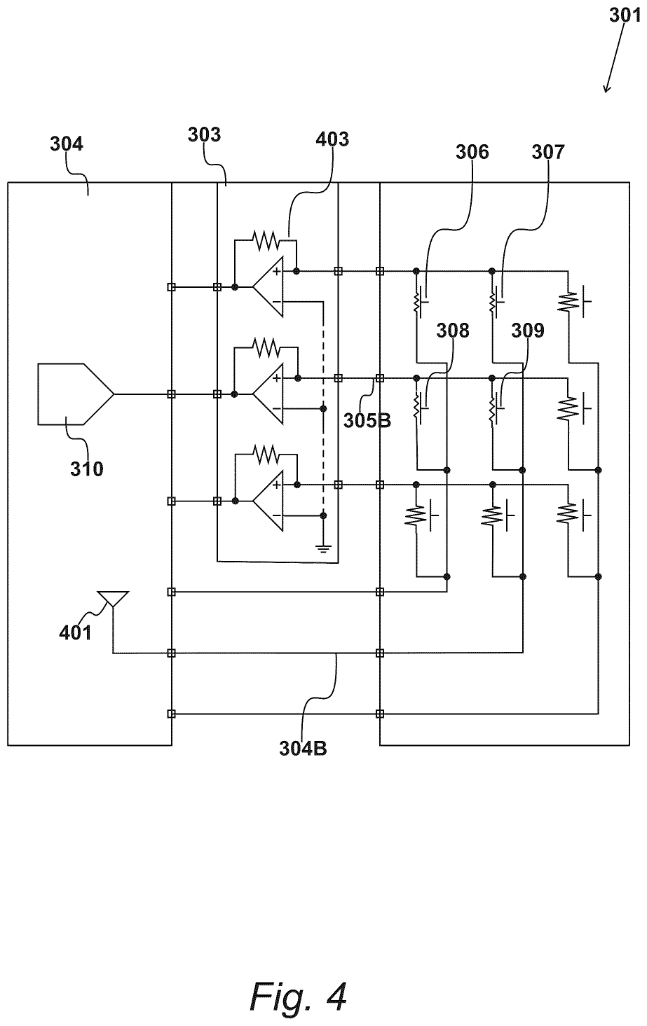

### FIG. 4

The schematic of apparatus 301 is shown again in FIG. 4, in which a force has been simultaneously applied to keys 306, 307, 308 and 309. In the embodiment, when a force is applied to each of the keys, the resistance at each of key is reduced. In this way, the current can flow more freely from the input provided on the drive lines to the output via the input amplifier 303 to the controller 304.

In the embodiment, a voltage is applied on drive line 304B and, when reading key 309, the current is transmitted along 304B and across line 305B via amplifier 403 to analogue digital converter 310. Although each key 306, 307 and 308 have been pressed, these are blocked due to the high voltage of 401. Although key 307 is activated on the same column as key 309, the conducting path through key 307 is not being read and interference is being prevented by means of amplifier 403, which allows for control of the voltage in the circuit.

In an alternative embodiment, the voltage amplifier may comprise a voltage buffer amplifier which is configured to drive the voltage potential of each of the non-activated drive lines and the non-activated sensing lines, and a multiplexer which is configured to activate each of the drive lines sequentially. This provides an alternative to providing a transimpedance amplifier on each sensing line. This is particularly advantageous for large sensing array matrixes as this can reduce the number of components required for key.

In the illustrated example comprising sensing elements, it is advantageous to acquire a reading in an analogue format, as this provides the entire spectrum of force for a given pressure applied. During the scanning process, each key comprising the sensing element can be modelled as a variable resistor to indicate the change in resistance with force applied.

Each transimpedance amplifier provides a controlled input voltage by means of the virtual earth which allows for absorption of current to the input node. Voltage can therefore be controlled at the input node and current flow can be blocked through the transimpedance amplifier as the current is absorbed.

In this way, the present invention allows for any number of keys to be pressed at a particular time and does not place any limitation of the size of the matrix array. In this way, in gaming applications, several keys may be pressed simultaneously, and this can be controlled over larger sized keyboards, with increased size matrixes.

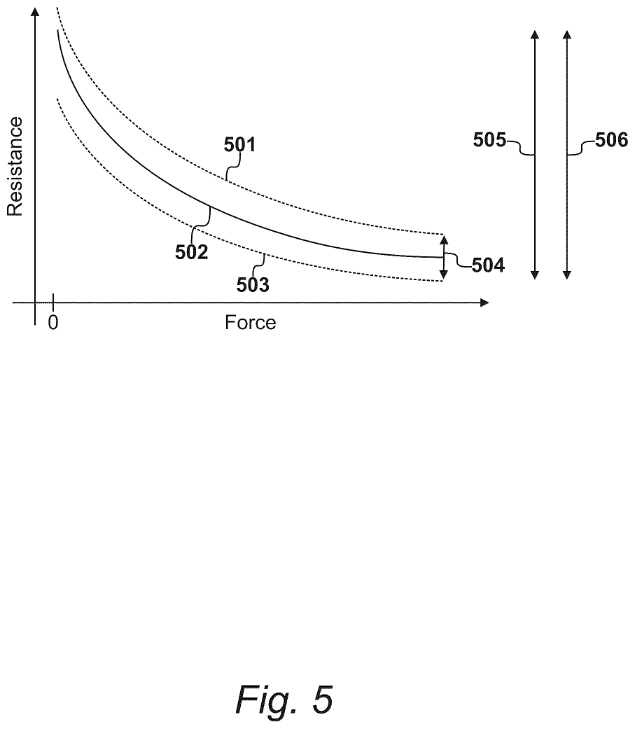

### FIG. 5

A graph showing typical force sensing characteristics of a sensing element used in a typical sensing array in line with the present application is shown in FIG. 5.

FIG. 5 shows a plot of a plurality of force resistance curves 501, 502 and 503 each representing an individual sensing element. Curve 502 represents an average force resistance response of a typical sensing element in accordance with the invention stop however, it is appreciated that for a plurality of sensing elements, such as those that make up an electronic keyboard, such as electronic keyboard 103 of FIG. 1, a variance 504 in the force resistance response, illustrated by curves 501 and 503 occurs from each sensing element. Variance 504 may be significant and can affect the outputs from the plurality of keys 104. Thus, when optimizing the response of any of keys 104, this factor must be taken into account.

In the embodiment, the force resistance responses present a dynamic range 505 of the force sensing device. In conventional systems, a corresponding dynamic range 506 for the analogue to digital converter (ADC) is matched to the dynamic range of the sensing elements 505 if there is no further calibration made system.

Thus, in this way, any force sensing devices with low sensitivity or resistance changes may utilize only a small portion of the dynamic range 506. This leads to poor sensitivity, poor signal-to-noise ratio (SNR), poor resolution and potentially low yield.

Consequently, while for some applications, utilizing a dynamic range 505 of the force sensing elements as being the same as the ADC dynamic range 506 may be sufficient, there remains a need to adapt the circuitry to enable adaptation of the dynamic range 506 of the analogue to digital converter.

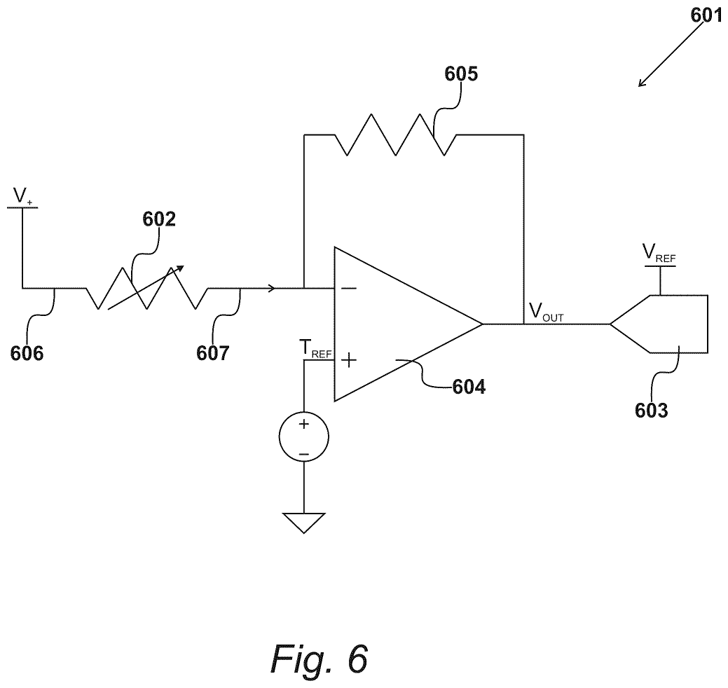

### FIG. 6

A schematic diagram of circuitry which may be utilized to control the dynamic range of the analogue to digital converter (ADC) is shown in FIG. 6.

The schematic circuit diagram shown shows an inverted amplifier mode. It is appreciated, however, that, the examples described within may further be provided as a non-inverted version by following substantially similar principles as to those described herein. However, for simplicity, the present application focuses on an inverted amplifier mode throughout and a single sensing element which may further form part of a sensing array and an electronic keyboard as described previously.

In the embodiment, apparatus 601 comprises a sensing element 602 which provides a force sensing resistor of variable resistance. Sensing element 602 is represented as a variable resistor and exhibits a variable resistance. A controller 603 comprises analogue digital converter which is configured to convert an analogue output from the force sensing resistor 602 to a digital output.

Sensing element 602 is electrically connected to controller 603 via a transimpedance amplifier 604 arranged with a gain resistor 605 and configured to transform the signal from sensing element 602 to a voltage for sampling by controller 603.

Conventionally, transimpedance amplifier 604 provides a signal gain through resistor 605 which is utilized to adapt the lowest measurable resistance from sensing element 602 to the lower range of controller 603. It is appreciated that, in the inverted amplifier mode as illustrated in FIG. 6, the resistance configured from sensing element 602 will be low and measured at the low end of the dynamic range of the analogue to digital converter. In an embodiment wherein the amplifier is provided in a non-inverted amplifier mode, the higher end of the analogue to digital converter dynamic range is configured by the corresponding circuitry.

In the embodiment, a voltage V+ is provided to drive sensing element 602 along drive line 606. When activated, the voltage through sensing element 602 passes through sensing line 607 through resistor 605 and transimpedance amplifier 604 to provide a voltage output V_{OUT}. In this mode, controller 603 is configured in a single ended mode and measures the output voltage V_{OUT} between a voltage from zero to the reference voltage V_{REF}. Thus, the output voltage can be calculated from the values of the resistance through force sensing element 602, gain resistor 605 and transimpedance amplifier 604.

The dynamic range of the analogue to digital converter can therefore be calculated as lying between infinity to a value calculated from the reference voltage (V_{REF}) multiplied by the gain resistance divided by the reference voltage (T_{REF}) from transimpedance amplifier 604.

In conventional systems, the parameters are typically set such that the dynamic range of the ADC 603 covers the complete dynamic range of sensing element 602. In some cases, as described previously, it may be difficult to achieve good signal-to-noise ratios, in particular in cases where the sensing elements have large variations. Thus, in some applications, it is preferable to allow for a narrow resistance range meaning that not only the lowest resistance but also the highest measurable resistance may be limited. The example shown in FIG. 6 may therefore be adapted to use a various combination of reference voltages to enable tailoring of the dynamic range.

For example, if the reference voltage (V_{REF}) is lowered to a value below the voltage from the transimpedance amplifier (T_{REF}), this can provide a compensation effect similar to the inclusion of an offset resistor. This method may produce a more suitable dynamic range in accordance with the invention.

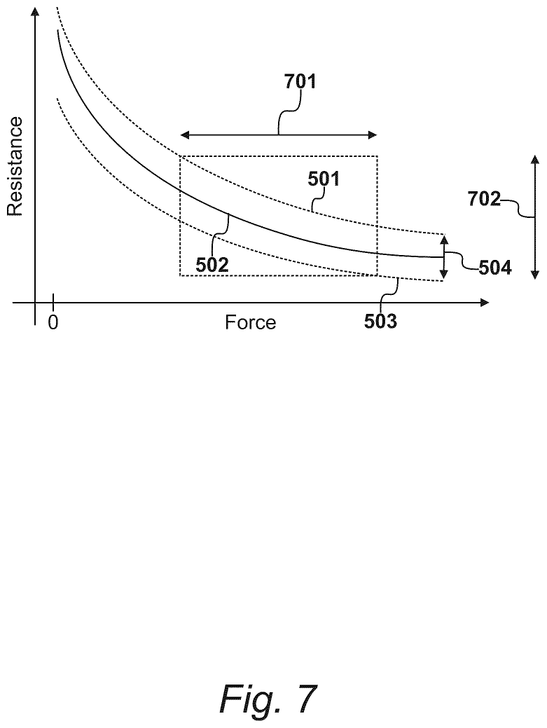

### FIG. 7

Thus, the embodiments described herein may provide an alternative approach consistent with the example shown in FIG. 7. FIG. 7 illustrates an alternative force resistance graph replicating the curves 501, 502 and 503 previously shown in FIG. 5. Each of the curves 501, 502 and 503 relate to respective sensing elements that may be present in an example electronic keyboard.

In the embodiment, an application range 701 is illustrated in which it is preferable to have sensitivity relating to the sensing elements used in the particular application. Thus, in the embodiment, the dynamic range 702 of the analogue to digital converter can be reduced in the manner shown in FIG. 7. Thus, the circuitry described herein tailors the performance of the sensing elements into a more desirable application range 701 while adapting to the variations between each of the sensing elements 504.

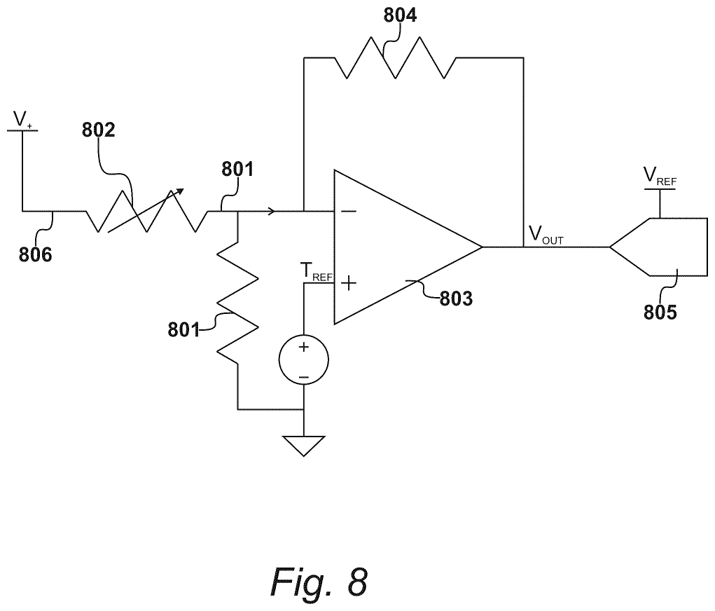

This optimized range may be created by the apparatus previously illustrated in respect of FIG. 6 but may also further be illustrated be provided by the embodiment illustrated with respect to FIG. 8.

### FIG. 8

A schematic circuit diagram for optimizing the dynamic range of the analogue to digital converter in line with the graph shown in FIG. 7, is shown in FIG. 8.

The embodiment of FIG. 8 is substantially similar to that of FIG. 6 save for the inclusion of an offset resistor 801 which provides further control and transformation of the response from sensing element 802 by limiting the highest measurable resistance. Thus, in the embodiment, the apparatus further comprises a transimpedance amplifier 803 and a gain resistor 804 which are again electrically connected between sensing element 802 and a controller comprising an analogue to digital converter 805.

In a similar manner, a voltage V+ is applied along a drive line 806 and is transmitted along sense line 807 following activation of sensing element 802. In the embodiment, the combination of resistors 801 and 804 allow the possibility to control both the upper and lower limits of the resistance range allowing the analogue to digital converter's dynamic range to be fully optimized to match the range of the force sensing elements used in the particular application.

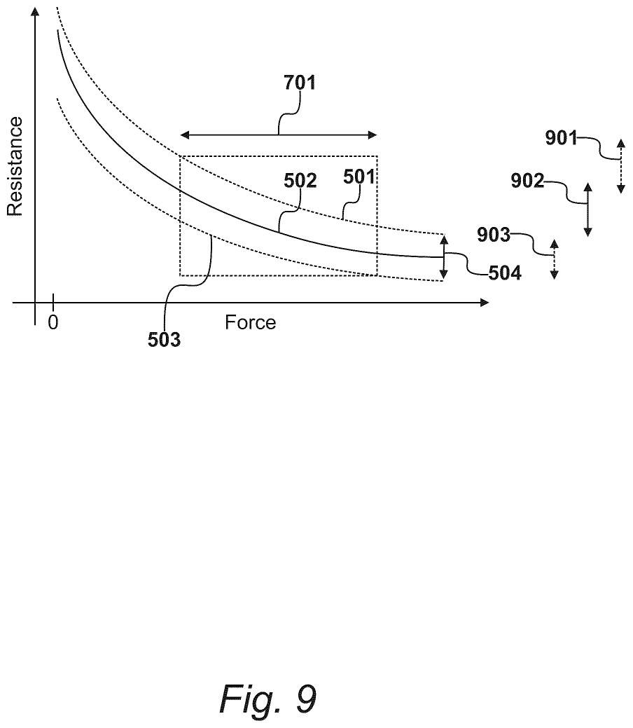

### FIG. 9

A further embodiment provides a further reconfiguration of the apparatus to include dynamic switching to provide further flexibility in relation to the yield and signal-to-noise ratio output. In the embodiment, the force resistance curves 501, 502 and 503 corresponding to a plurality of sensing elements have variations 504 and an application range 701. However, in addition to this, calibration of each sensing element may produce three separate dynamic ranges 901, 902 and 903 for the analogue to digital controller. Dynamic ranges 901, 902 and 903 correspond to force-resistance curves 501, 502 and 503 respectively.

In this way, the apparatus may be configured to enable selection of each dynamic range 901, 902 and 903 depending on requirements of the application in question.

These narrower ranges may be utilized to improve the signal-to-noise ratio qualities in particular cases where the force-resistance response comprises a substantially lower gradient. A wider range may further improve the yield by allowing a sensing element with a more significant change in resistance to operate within the measurable range of the analogue-to-digital converter.

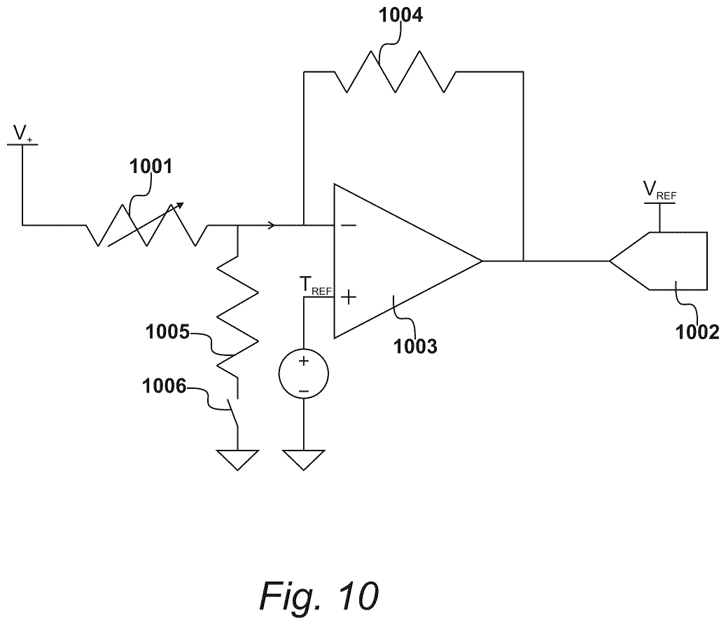

An example circuit providing this is illustrated in respect of FIG. 10.

### FIG. 10

In the embodiment, sensing element 1001 is electrically connected to analogue-to-digital converter 1002 via transimpedance amplifier 1003 and gain resistor 1004. An offset resistor 1005 is further included and is provided with an electrical switch 1006 which is configured to activate and deactivate the offset resistor 1005 as necessary. Thus, in this embodiment, further control of the range can be made by activating and deactivating switch 1006 as necessary. This is beneficial to enable control of both upper and lower ranges.

This provides a comparative low-cost solution as it is only required to provide a single switch control and a plurality of fixed resistors in addition to existing circuitry.

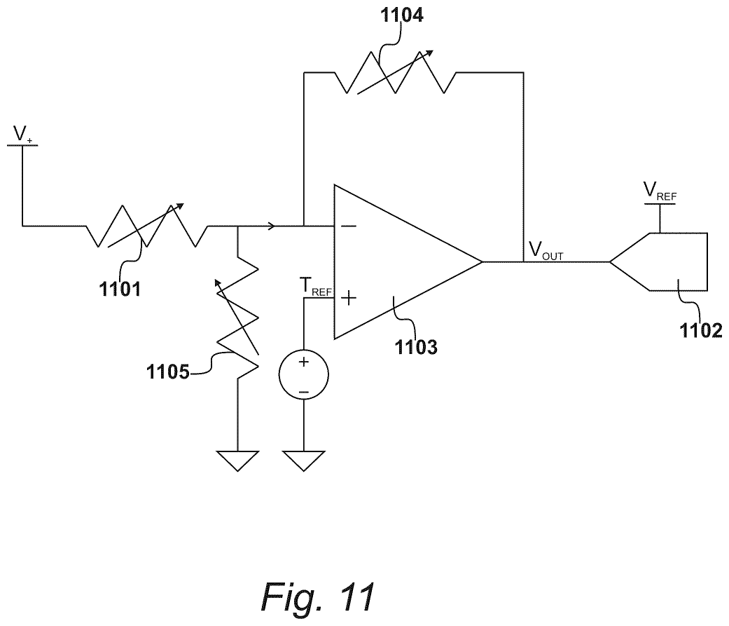

### FIG. 11

A further schematic diagram of a circuit in a further example embodiment in accordance with the invention shown in FIG. 11.

In the embodiment, the circuit of FIG. 11 is substantially similar to the circuit previously shown in FIG. 8, in that the circuit comprises a sensing element 1101 and an analogue-to-digital converter 1102 which are both electrically connected via the transimpedance amplifier 1103 and resistor 1104. An offset resistor 1105 is further included in the embodiment.

In the embodiment, the fixed resistors of FIGS. 8 and 10 have been replaced by high-resolution digital controlled resistor arrays (RDAC). This provides a further more sophisticated solution with variable resistance incorporated. It is appreciated however that its use may be cost dependent.

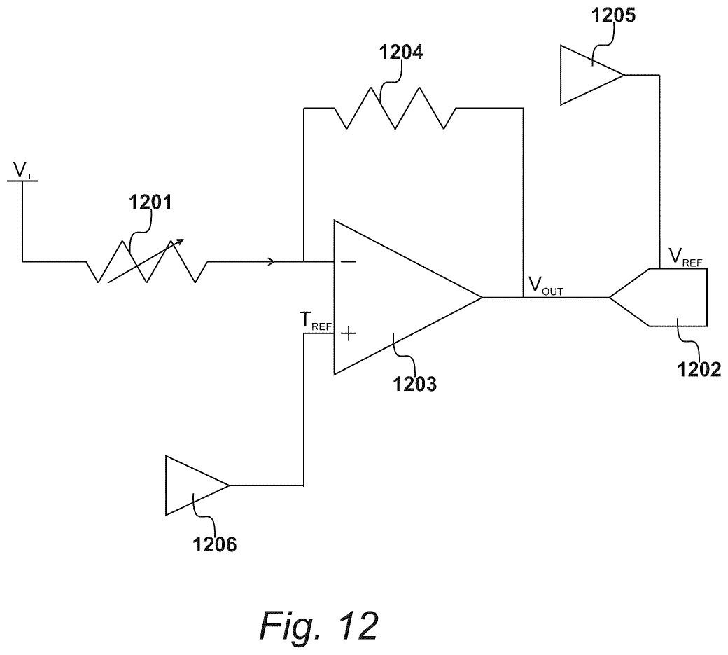

### FIG. 12

A schematic diagram of a circuit of a further embodiment which comprises dynamic switching shown in FIG. 12.

In the embodiment, sensing element 1201 is again connected to the analogue-to-digital converter 1202 by means of the transimpedance amplifier 1203 and gain resistor 1204.

In the embodiment, the reference voltages from the analogue-to-digital converter 1202, V_{REF} and transimpedance amplifier 1203 T_{REF} are digitally controlled with voltage digital to analogue converters (DAC).

Thus, in the embodiment of FIG. 12, an n-bit digital to analogue converter 1205 is connected to analogue-to-digital converter 1202 and a further n-bit digital to analogue converter 1206 is electrically connected to transimpedance amplifier 1203. These correspondingly allow for further digital control and dynamic switching of the reference voltages V_{REF} and T_{REF} respectively.

This combination of reference voltages may provide a substantially similar range of optimization of the analogue to digital converter shown in previous examples which utilize corresponding resistors. However, this particular option may be more cost effective than the example shown in FIG. 11 specifically in cases where one or more voltage DACs are inbuilt within the system already.

The invention claimed is:

1. Apparatus for controlling a dynamic range of a controller for a force sensing device, comprising:
a plurality of drive lines and a plurality of sensing lines arranged to provide a plurality of intersections defining a plurality of keys;
each of said plurality of keys comprising a sensing element which exhibits a variable resistance;
said controller is configured to convert an analogue output from each of said sensing elements to a digital output, each of said sensing elements being electrically connected to said controller and configured to transform a signal from each of said sensing elements for sampling by said controller; and said apparatus further comprising:
an input amplifier configured to provide signal gain, such that, said dynamic range of said controller is adapted by means of said signal gain, said input amplifier comprising a transimpedance amplifier electrically connected to a gain resistor and arranged to control upper and lower limits of a resistance range to allow said dynamic range to match an application range of said sensing elements.

2. The apparatus of claim 1, wherein said signal gain is provided by means of said gain resistor.

3. The apparatus of claim 1, wherein said gain resistor comprises a high resolution digital controlled resistor array.

4. The apparatus of claim 1, further comprising an offset resistor configured to limit an upper limit of a resistance measured from a corresponding one of said sensing elements.

5. The apparatus of claim 4, further comprising an electrical switch configured to activate and deactivate said offset resistor.

6. The apparatus of claim 4, wherein said offset resistor comprises a high resolution digital controlled resistor array.

7. The apparatus of claim 1, wherein said input amplifier is further configured to provide a voltage potential to each non-activated drive line of said plurality of drive lines and each non-activated sensing line of said plurality of sensing lines.

8. The apparatus of claim 1, wherein said plurality of drive lines are arranged as a plurality of columns and said plurality of sensing lines are arranged as a plurality of rows to form a sensing array.

9. The apparatus of claim 1, wherein each of said sensing elements comprises a quantum tunnelling material.

10. The apparatus of claim 1, further comprising a voltage digital-to-analogue converter configured to control a reference voltage.

11. The apparatus of claim 1, wherein said apparatus forms part of an electronic keyboard.

12. An electronic device comprising the apparatus of claim 1.

13. A method of controlling a dynamic range of a controller for a force sensing device, comprising steps of:
providing an apparatus comprising a plurality of drive lines and a plurality of sensing lines arranged to provide a plurality of intersections defining a plurality of keys, each of said plurality of keys comprising a sensing element which exhibits a variable resistance, each of said sensing elements being electrically connected to said controller and configured to transform a signal from each of said sensing elements for sampling by said controller;
activating one of said sensing elements in response to a mechanical interaction;
providing a current in response to said mechanical interaction from said one of said sensing elements to an input amplifier comprising a transimpedance amplifier electrically connected to a gain resistor and arranged to control upper and lower limits of a resistance range to allow said dynamic range of said controller to match an application range of said sensing elements;
receiving a signal gain from a response to said input amplifier; and
adapting said dynamic range of said controller configured to convert an analogue output from each of said sensing elements to a digital output by means of said signal gain.
